(19) United States
(12) Patent Application Publication
(10) Pub. No.: US 2025/0383198 A1
(43) Pub. Date: Dec. 18, 2025

(54) METHOD FOR THE INTERFEROMETRIC DETERMINATION OF THE SURFACE SHAPE OF A TEST OBJECT

(71) Applicant: Carl Zeiss SMT GmbH, Oberkochen (DE)

(72) Inventor: Michael PATRA, Oberkochen (DE)

(21) Appl. No.: 19/312,370

(22) Filed: Aug. 28, 2025

Related U.S. Application Data
(63) Continuation of application No. PCT/EP2024/052340, filed on Jan. 31, 2024.

(30) Foreign Application Priority Data
Feb. 28, 2023 (DE) 10 2023 201 790.3

(51) Int. Cl. G01B 11/24; G03F 7/00

(52) U.S. Cl. CPC G01B 11/2441; G03F 7/70591

(57) ABSTRACT

Methods for interferometrically determining the surface shape of a test object. In one aspect, in the test arrangement (100) a test wave, generated from electromagnetic radiation and reflected from the test object (110), is overlaid with a reference wave, which is split in reflection from the test wave at a reference surface (121) of a reference element (120) before this test wave hits the test object. The test object is designed for installation in a predefined installation position in an optical system (700). The reference surface is designed based on a measurement previously carried out on the reference element in a predefined installation position in a measuring system (800). The surface shape of the test object in the test arrangement is determined taking account of both the installation position of the test object in the optical system (700) and the installation position of the reference element in the measuring system.

### CROSS REFERENCE TO RELATED APPLICATIONS

This is a Continuation of International Application PCT/EP2024/052340 which has an international filing date of Jan. 31, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 201 790.3 filed on Feb. 28, 2023.

### FIELD

The invention relates to a method for an interferometric determination of the surface shape of a test object. The test object may be in particular an optical element (e.g. a mirror) of a microlithographic projection exposure apparatus.

### BACKGROUND

Microlithography is used for producing microstructured components, such as for example integrated circuits or liquid crystal displays (LCDs). The microlithography process is carried out in what is referred to as a projection exposure apparatus, which comprises an illumination device and a projection lens. The image of a mask (=reticle) illuminated by the illumination device is projected by the projection lens onto a substrate (for example a silicon wafer) that is coated with a light-sensitive layer (photoresist) and arranged in the image plane of the projection lens in order to transfer the mask structure to the light-sensitive coating of the substrate.

In projection lenses designed for the extreme ultraviolet (EUV) wavelength range, i.e. at wavelengths of for example approximately 13 nm or approximately 7 nm, mirrors are used as optical components for the imaging process owing to the lack of availability of suitable light-transmissive refractive materials. Typical projection lenses designed for EUV, as known for example from US 2016/0085061 A1, may have for example an image-side numerical aperture (NA) in the region of NA=0.55 and image an (e.g. ring-segment-shaped) object field into the image plane or wafer plane.

The increase in the image-side numerical aperture (NA) is typically accompanied by an enlargement of the required mirror surface areas of the mirrors used in the projection exposure apparatus. In view of the high precision requirements in microlithography, this means that not only production, but also the testing of the surface shape, in particular of EUV mirrors, constitutes a demanding challenge. Interferometric measurement methods, in particular, are used here for highly accurate testing of the mirrors. The determination of the surface shape of the respective mirror or test object is based on an interferometric superposition of a test wave having a wavefront adapted to the target shape of the surface of the test object and a reference wave (depending on the interferometric measurement setup, potentially also adapted to the surface of the test object).

Different approaches exist for the generation of the reference wave required for interferometric measurement, e.g. the arrangement of a reference mirror in the optical beam path of a so-called reference mirror interferometer or the use of a Fizeau element in a Fizeau interferometer. A further approach is to generate the reference wave required for interferometric measurement or superposition with the test wave reflected at the test object by being split from the test wave, which is achieved in reflection via a reference surface, located upstream of the test object in the optical beam path, of a reference element (also known as “matrix”).

A problem that occurs in practice with regard to the most reliable and accurate interferometric determination of the mirror surfaces possible is that the specific conditions of use of the respective test object or mirror in the actual optical system or the microlithographic projection exposure apparatus differ from those in the testing of the respective surface shape in the interferometric test arrangement. In this respect, there are generally differences, on the one hand, with regard to the geographical position and the resulting locally different gravitational effect, and on the other hand with regard to the specific installation position in the respective optical system or test system. The result is in each case a different shape deviation or deflection in the different scenarios or installation positions. This, in turn, leads to optical aberrations when using the mirror, produced on the basis of the surface test, in the projection exposure apparatus.

The abovementioned problems due to different installation positions do not occur only with regard to the respective test object or mirror, but also potentially with regard to the reference element used in the interferometric test arrangement (i.e., potentially in particular the “matrix”). This reference element or the matrix is actually likewise generally measured interferometrically for the precise production (typically adapted to the test object geometry) of the reference surface, wherein in this respect too different installation positions lead to mutually different deflections in the respective scenarios (i.e. in the interferometric measurement arrangement used for this purpose for determining the surface shape of the reference element on the one hand and in the interferometric test arrangement for determining the surface shape of the mirror on the other).

With the problems described above, it must be taken into account in each case that the respective installation positions of the mirrors in the microlithographic projection exposure apparatus are usually fixed by the specific optical design and existing installation space limitations, wherein in the measurement arrangements used for interferometric measurement of the reference element used in the test arrangement typically only a low flexibility with regard to the respective installation position exists.

The effect of external forces causes a deflection or deformation of the mirrors, which is more pronounced the larger the diameter of the mirror is and the less stiff it is. The deflection of an object results as a quotient of the applied bending moment and stiffness. Since this stiffness refers to deflection, it is also called bending stiffness.

The stiffness of a mirror does not substantially depend on its diameter, but only on its cross-sectional profile or thickness and on its material. The stiffness can be written as a product of the modulus of elasticity, i.e. a material property, and the geometric moment of inertia, i.e. a geometry size that describes the cross section.

A larger diameter of a mirror leads to a stronger deformation or deflection with the same mirror cross section and the same material, i.e. the same stiffness, because the applied bending moment increases with the diameter. The increase of the image-side numerical aperture of the projection exposure apparatus mentioned in the introductory part leads to an increase in the mirror diameter, while at the same time the stiffness cannot increase to the extent necessary to keep the deformation constant, or even decreases.

For deformations or deflections based on the effect of gravity, the bending moment is proportional to the mass or mass density of the object. The relevant amount to describe the extent of deformation or deflection is therefore the specific bending stiffness, which will only be referred to briefly as stiffness in the following text.

Regarding the prior art, reference is made merely by way of example to DE 10 2021 205 774 A1 and DE 10 2021 202 909 A1.

### SUMMARY

Against the above background, it is an object of the present invention to provide methods for interferometric determination of the surface shape of a test object, which allow a reliable test and determination of the surface shape with at least partial avoidance of the problems described above.

This and other objects are achieved by the features articulated in the independent patent claims.

According to one aspect, the invention relates to a method for an interferometric determination of the surface shape of a test object,
wherein in a test arrangement, a test wave, which is generated from electromagnetic radiation and has been reflected at the test object, is superposed with a reference wave, which is split off from the test wave in reflection, before its incidence on the test object, at a reference surface of a reference element;
wherein the test object is designed for installation in an optical system in a specified installation position;
wherein the design of the reference surface is based on a measurement carried out in advance on the reference element in a measurement system in a specified installation position; and
wherein the surface shape of the test object is determined in the test arrangement, taking into account both the installation position of the test object in the optical system and the installation position of the reference element in the measurement system.

This aspect of the invention proceeds from the approach of generating in a measurement arrangement for interferometric determination of the surface shape of a test object (in particular EUV mirror) the reference wave required for the interferometric measurement or the superposition with a test wave reflected at the test object via a split from the test wave achieved in reflection via a reference surface located upstream of the test object in the optical beam path, as is described below with reference to FIGS. 1-2. In this case, a design of this reference surface similar to the test object surface leads to the wavefronts of the test wave and reference wave being configured similarly or identically to each other.

Based on this approach, the invention includes a concept of choosing the installation position in a suitable manner in the interferometric determination of the surface shape of the test object in the test arrangement so that the installation positions both of the test object in the actual optical system or the projection exposure apparatus and also of the reference element or the matrix in the measurement system (used for characterizing or designing the reference surface thereof), which are generally different from the former, are taken into account. The invention includes in particular the consideration that-in contrast to the installation positions in the microlithographic projection exposure apparatus or the measurement arrangement for the reference element-a comparatively flexible choice of the installation position of the test object or reference element is generally feasible in such a test arrangement.

As a result, an error contribution resulting from existing differences between the respective installation positions of the test object in the optical system and in the test arrangement and/or between the respective installation positions of the reference element in the test arrangement and the measurement system is reduced according to this aspect of the invention.

According to one embodiment, either α₁<α<α₂ or α₁>α>α₂, with:
α₁=tilt angle of the test object in the test arrangement in the installation position in the optical system;
α₂=tilt angle of the reference element in the installation position in the measurement system; and
α=tilt angle of the test object in the test arrangement;
wherein the tilt angle is related to the tilt of the test object or the reference element about an axis of rotation perpendicular to the plane of symmetry.

Thus, according to this aspect of the invention, the tilt angle of the test object in the test arrangement (or the tilt angle of the matrix in this test arrangement, which typically corresponds thereto due to the measurement principle) is selected as the degree of freedom in order to ultimately reduce or minimize the undesirable above-described effects of different installation positions in the projection exposure apparatus, test arrangement and measurement system. In this case, the choice of the installation position or tilt in the test arrangement (hereinafter also referred to as “orientation”) is preferably made, according to an aspect of the invention, such that this orientation lies between the respective orientations or tilts in the optical system and in the measurement system for the reference element or the matrix. This approach is based on the further consideration that the dependence of the undesirable deformation on the orientation difference is non-linear (in the lowest approximation or order squared). As a result, the overall effect of the different installation positions when “dividing” the orientation difference set in the test arrangement between the optical system and the measurement system is ultimately less detrimental to the performance of the optical system or the projection exposure apparatus than in the case where the orientation of the test object and the matrix in the test arrangement were chosen in complete agreement with either the optical system or the measurement system, since in this case the influence of the maximum large misorientation in the respective other system is particularly great.

According to one embodiment, the test object has a first stiffness S₁ and the reference element has a second stiffness S₂, wherein at least one of the following conditions is met:

$$for {S}_{1} < {S}_{2} : \vert α - {α}_{1} \vert < \vert α - {α}_{2} \vert ;$$

$$for {S}_{1} > {S}_{2} : \vert α - {α}_{1} \vert > \vert α - {α}_{2} \vert ;$$

$$for {S}_{1} = {S}_{2} : \vert α - {α}_{1} \vert = \vert α - {α}_{2} \vert = α / 2.$$

These designs are based on the further consideration that, at different stiffnesses, the overall orientation difference to reduce or minimize the negative effects is preferably distributed so that in the scenario with comparatively greater stiffness, the relatively larger misorientation is allowed in order to achieve a better approximation to the orientation there for the respective other, comparatively more deformation-sensitive scenario.

The invention further relates to a method for an interferometric determination of the surface shape of a test object,
wherein in a test arrangement, a test wave, which is generated from electromagnetic radiation and has been reflected at the test object, is superposed with a reference wave, which is split off from the test wave in reflection, before its incidence on the test object, at a reference surface of a reference element;
wherein the test object is designed for installation in an optical system in a specified installation position;
wherein the design of the reference surface is based on a measurement carried out in advance on the reference element in a measurement system; and
wherein the determination of the surface shape of the test object in the test arrangement takes place taking into account a systematic error contribution, which is ascertained on the basis of a plurality of system measurements which are carried out in advance for a plurality of optical systems constructed with different test objects.

According to this aspect, the invention includes the further consideration that with regard to the errors (e.g. in the form of wavefront aberrations) occurring in the optical system or the projection exposure apparatus after their construction (at the “end customer”), different causes may exist, wherein in addition to the abovementioned installation position effects, errors in the original production of the respective mirrors as well as errors caused by the transport to the end customer should be mentioned. By measuring the respective system properties for a large number of constructed optical systems (with different test objects or mirrors), systematically occurring errors can now be distinguished from non-systematic (e.g. randomly occurring) errors. Based on this consideration, this aspect of the invention now includes the further concept of allowing the information obtained regarding the systematic error contributions to be already incorporated into the determination of the surface shape of the test object or mirror in the test arrangement insofar as, for example, the reference element or the matrix is adapted accordingly with the aim that the mirrors subsequently produced in this way no longer contain the corresponding systematic errors, or contain them only to a reduced extent.

In further embodiments, instead of an adaptation or reworking of the reference element (matrix), a different specification shape for the test object or mirror can be used as a basis in the test arrangement, wherein in turn a “presentation” of the previously ascertained systematic errors is already realized in the mirror production of future produced mirrors based on the interferometric test.

According to one embodiment, the systematic error contribution is taken into account in that a reworking of the reference surface of the reference element is carried out dependent on the systematic error contribution.

According to one embodiment, the measurement system has a diffractive optical element, in particular a computer-generated hologram, which generates the test wave by diffraction of electromagnetic radiation.

In accordance with one embodiment, the test object to be characterized with respect to its surface shape has an optical effective surface in the form of a freeform surface without rotational symmetry.

In accordance with one embodiment, the test object is a mirror or a lens element.

In accordance with one embodiment, the test object is designed for an operating wavelength of less than 30 nm, in particular less than 15 nm.

In accordance with one embodiment, the test object is a microlithographic optical element, in particular of a microlithographic projection exposure apparatus.

Further refinements of the invention can be gathered from the description and the dependent claims.

These aspects of the invention will be explained in detail below on the basis of exemplary embodiments illustrated in the appended figures.

### BRIEF DESCRIPTION OF THE DRAWINGS

In the figures:

FIG. 1 shows a schematic illustration for explaining the construction of a test arrangement used in a method according to the invention with reference to an exemplary embodiment;

FIGS. 2-3 show schematic illustrations for explaining the concept on which a method associated with the invention according to a first aspect is based, wherein

FIG. 3 depicts thicknesses differing from those of FIG. 2;

FIG. 4 shows a flow chart for explaining the concept on which a method associated with the invention in accordance with a second aspect is based;

FIGS. 5A-5C show schematic illustrations for further explanation of the concept on which a method associated with the invention according to the second aspect is based, namely three exemplary deviations among respective surface shapes;

FIG. 6 shows a further flow chart for explaining the concept on which a method associated with the invention according to the second aspect is based in a further embodiment;

FIG. 7 shows a schematic illustration of a projection exposure apparatus designed for operation in the EUV as an example of an optical system used in a method associated with the invention; and

FIG. 8 shows a schematic illustration of a feasible construction of an interferometric measurement arrangement used in a method associated with the invention.

### DETAILED DESCRIPTION

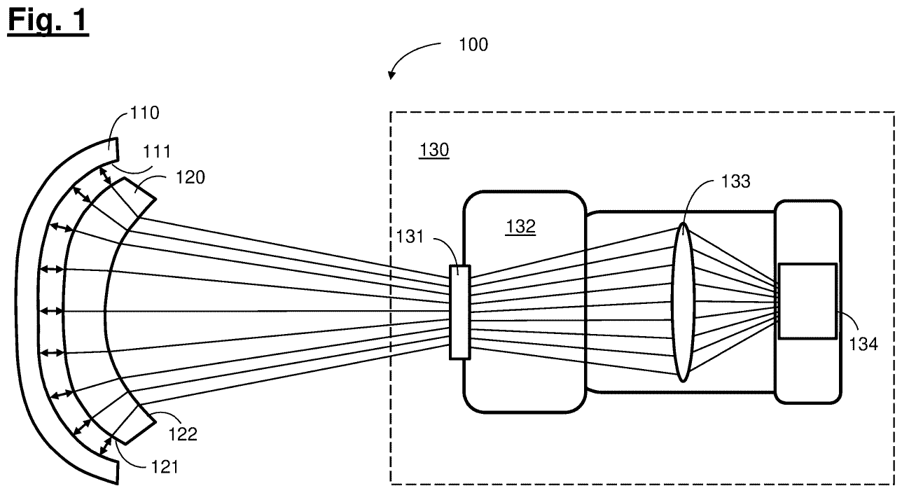

FIG. 1 shows a schematic illustration for explaining the feasible construction of a measurement arrangement according to an aspect of the invention in one exemplary embodiment.

For the explanation of exemplary embodiments of a method according to one aspect of the invention, FIGS. 1, 7 and 8 each show examples of feasible designs of optical systems used in this case in schematic and simplified illustrations.

In detail, FIG. 1 shows a feasible design of a test arrangement for interferometric determination of the surface shape of a test object 110, wherein, according to the principle of the matrix test technique already explained in the introductory part, a reference wave required for interferometric superposition with a test wave reflected at the test object 110 is generated via a split achieved in reflection via a reference surface 121 of a reference element 120 located upstream of the test object 110 in the optical beam path. For the sake of a better overview, a light source, which generates the light radiation underlying the test wave and the reference wave, is not shown here.

In detail, FIG. 1 shows a feasible design of a test arrangement for interferometric determination of the surface shape of an optical surface 111 of a test object 110 according to the principle of the matrix test technique already explained in the introductory part. A test wave generated at the optical surface 111 of the test object 110 is superposed with a reference wave, which is generated in reflection at a reference surface 121 of a reference element 120 arranged upstream of the test object 110 in the optical radiation path.

The distance between the optical surface 111 and the reference surface 121 is less than 10 mm, in particular less than 1 mm; it may also be less than 100 μm. The shape of the reference surface 121 is thus largely defined by the shape of the optical surface 111. The test wave is incident substantially perpendicular on the optical surface 111 of the test object 110, e.g. at an angle relative to the surface normal of less than 1°, in particular less than 10 mrad, further in particular less than 100 prad. This is achieved by a suitable shape of a beam shaping surface 122 of the reference element 120. The beam path between the beam shaping surface 122 and the reference surface 121 is caustic-free.

The test object 110 and the reference element 120 are spaced apart from the actual measurement system 130. The measurement system 130 comprises a beam generation system 132 and an exit element 131. The beam generation system 132 generates the measurement radiation, from which the test wave and the reference wave are generated later in the beam path. The exit element 131 provides illumination of a sufficiently large region of the beam shaping surface 122 of the reference element 120 so that the entire region to be tested of the optical surface 111 is illuminated. The beam path between the exit element 131 and the beam shaping surface 122 is caustic-free.

A beam splitter (not shown in FIG. 1) enables the exit element 131 to be imaged on a spatially resolved sensor 134, e.g. a camera, with an optical unit 133. The exit element 131 and the sensor 134 are thus optically conjugate to each other, and together with being caustic-free, there is thus a 1:1 correspondence of positions on the optical surface 111 and the reference surface 121 on the one hand and positions on the sensor 134 on the other. The interference between the test wave and the reference wave based on the difference between the surface profile of the optical surface 111 and the surface profile of the reference surface 121 can thus be converted by the sensor 134 into spatially resolved information about the surface profiles.

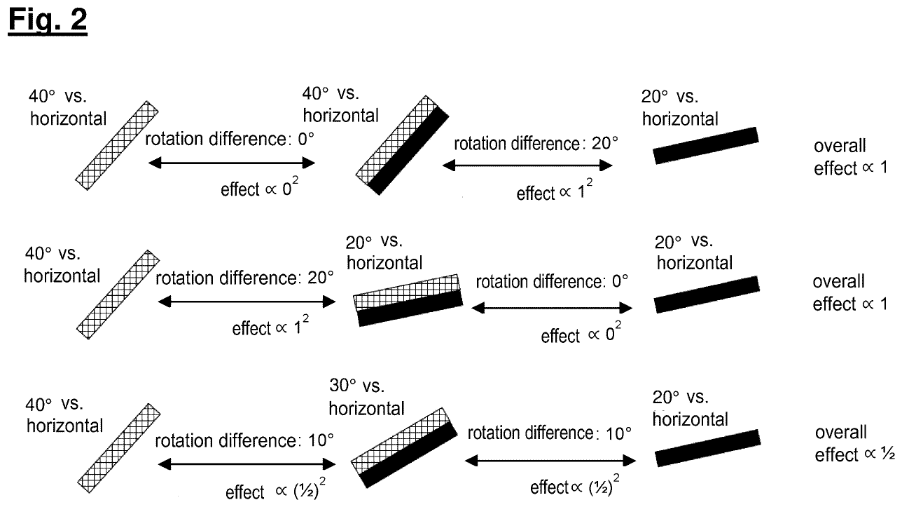

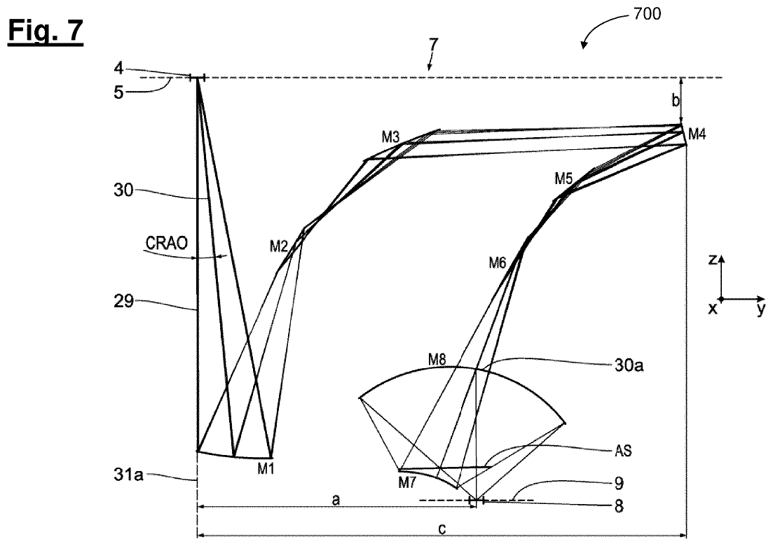

FIG. 7 again shows only an example of a feasible specific design of a projection lens of a microlithographic projection exposure apparatus, with reference being made to DE 10 2021 205 774 A1 (see FIG. 2 thereof) for a detailed description. The optical system or projection lens according to FIG. 7, in which the different installation positions of the mirrors used can be seen, is selected merely as an example (and without the invention being limited thereto).

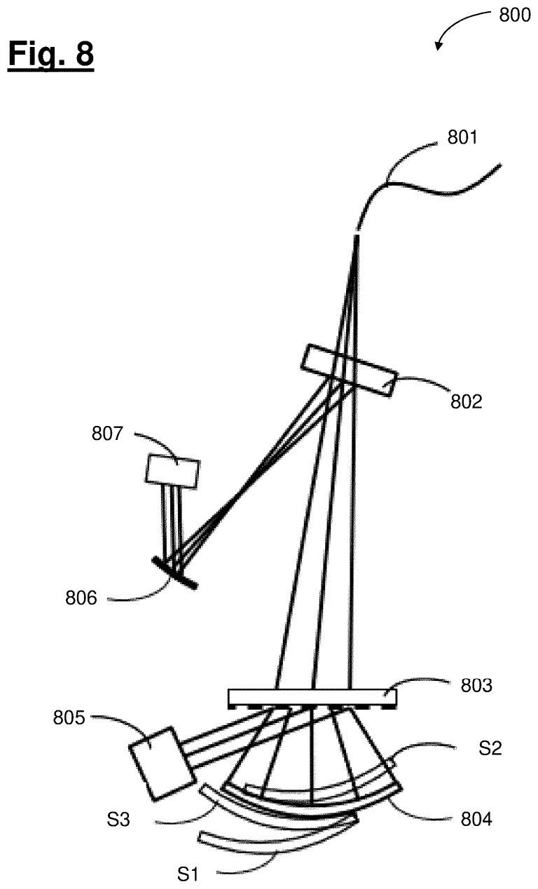

Finally, FIG. 8 shows in a schematic illustration the feasible design (known per se) again of an interferometric measurement system, with which the reference element or its reference surface can be measured in advance. In this case, electromagnetic radiation generated by a light source (not shown) passes via an optical fiber 801 and a beam splitter 802 to a CGH 803, which generates, by suitable complex coding, in addition to a test wave, further output waves, namely a reference wave again required here for an interferometric measurement and a plurality of calibration waves. According to the embodiment, the measurement system thus comprises a diffractive optical element, in particular a computer-generated hologram CGH 803, which generates the test wave by diffraction of electromagnetic radiation. The reference wave is reflected via a reference mirror 805, which is arranged downstream of the CGH 803 in the optical beam path. The calibration waves are reflected at different calibration mirrors S1-S3 and are also interferometrically superposed with the reference wave in the measurement arrangement. An interferometer camera 807 downstream of an eyepiece 806 in the optical beam path captures an interferogram, which is generated by the interfering waves and from which the surface shape of the reference element 804 is determined with an evaluation device (not illustrated).

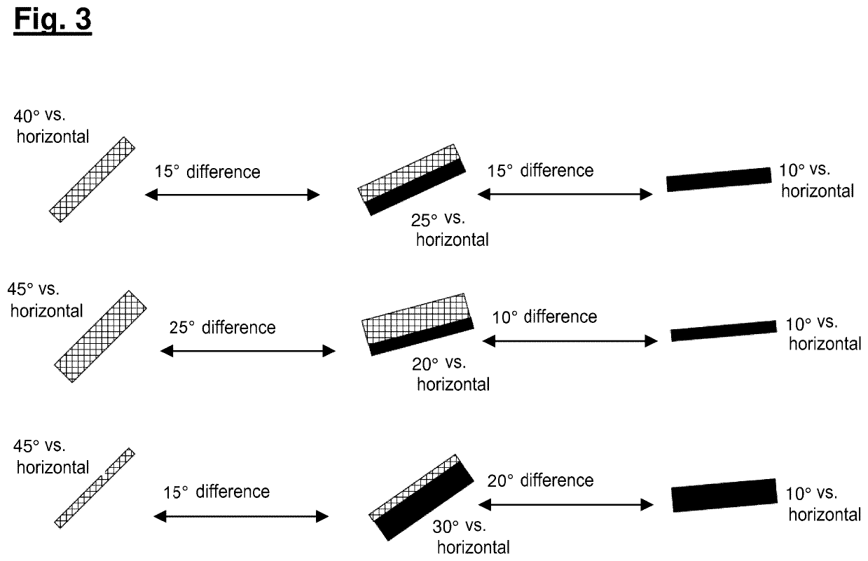

According to a first concept illustrated in FIGS. 2-3 in different embodiments, the orientation of the test object 110 or the orientation of the reference element 120, which generally corresponds to the former, is now used as a degree of freedom in the interferometric test arrangement 100 of FIG. 1 in order to reduce or minimize the negative effects described in the introductory part of the respective different installation positions of the test object 110 or reference element 120 in the optical system 700 according to FIG. 7 or the measurement system 800 according to FIG. 8.

In this case, this orientation or tilt in the interferometric test arrangement 100 is shown both in FIG. 2 and in FIG. 3 in the middle column for different scenarios, in the respective left column the orientation or tilt of the test object in the optical system 700 according to FIG. 7 and in the right column the orientation or tilt of the reference element (“matrix”) in the measurement system 800 of FIG. 8.

Furthermore, for the sake of simplicity (but without limiting the generality with regard to the advantageous effect achieved according to aspects of the invention), a quadratic dependence of the ultimately occurring undesirable deformation on the respective orientation difference is used as a basis, wherein the respectively specified tilt angle values are also selected merely as examples.

With reference initially to FIG. 2 (in which the corresponding thicknesses or stiffnesses of the test object 110 and the reference element 120 or matrix are used as a basis), it is clear that the overall effect of the installation positions or orientations present in the different systems is reduced or minimized in particular when the orientation or the tilt angle in the interferometric test arrangement 100 is selected between the respective orientations or tilt angles in the optical system 700 on the one hand and the measurement system 800 for the reference element 120 on the other hand, in other words, the entire orientation difference is divided between the individual orientation differences between the optical system 700 and the test arrangement 100 on the one hand and between the test arrangement 100 and the measurement system 800 on the other.

With reference to FIG. 3, however, it becomes clear that at different stiffnesses, which can be based, for example, as indicated in FIG. 3 on different thicknesses of the components, of the test object 110 and the reference element 120 or matrix, it is advantageous in the sense of minimizing the overall effects of the orientation differences if the orientation or the tilt angle in the test arrangement 100 is selected with comparatively stronger adaptation to the scenario that is more sensitive with regard to the deformations occurring: This means that at a lower stiffness of the reference element 120 in comparison with the test object 110 or mirror (according to the middle line in FIG. 3). preferably a comparatively stronger adaptation of the orientation in the test arrangement 100 to the orientation of the reference element 120 in the measurement system 800 takes place, whereas in the case of a comparatively lower stiffness of the test object 110, the orientation or the tilt angle in the test arrangement 100 is more closely adapted to the orientation of the respective test object 110 in the optical system 700 or the projection exposure apparatus.

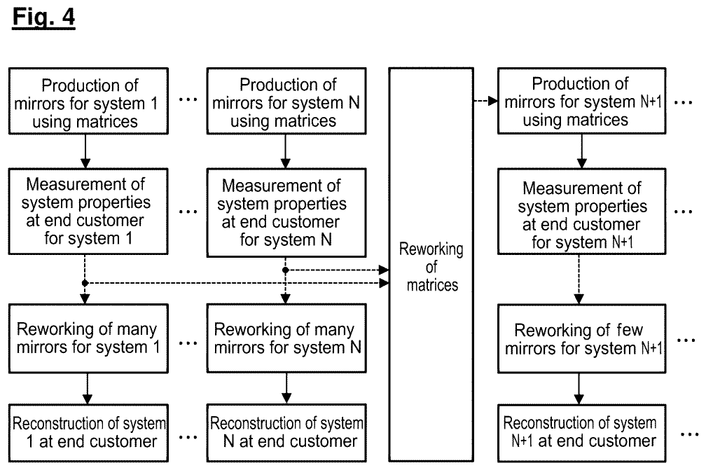

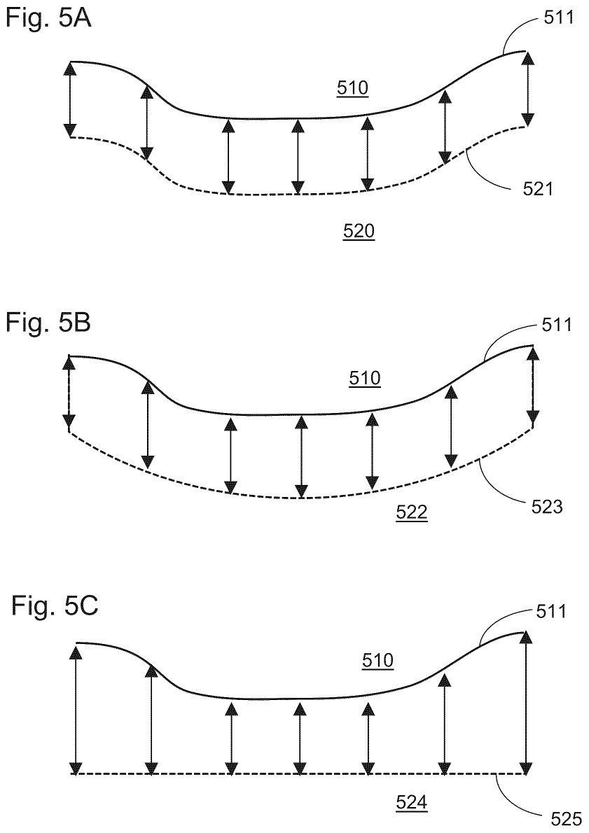

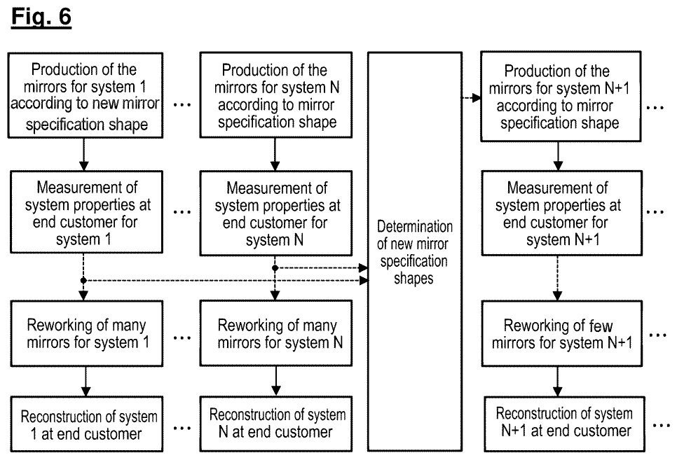

According to a further concept described with reference to the flow charts of FIG. 4 and FIG. 6 and also the schematic illustrations of FIGS. 5A-5C, the determination of the surface shape of the test object 110 taking place in the interferometric test arrangement 100 and the specific design of the reference element 120 used in this test arrangement 100 can, according to an aspect of the invention, also be used to present previously ascertained systematic deviations or errors of the test object 110 accordingly (in the sense that mirrors that will be manufactured on the basis of the corresponding interferometric test no longer possess this systematic error).

In this case, according to the flow chart of FIG. 4 and also according to the flow chart of FIG. 6, the information regarding systematic errors is obtained on the basis of a plurality of optical systems constructed in each case at the end customer as well as corresponding measurements of the system properties. The embodiments according to FIG. 4 and FIG. 6 differ in that, according to FIG. 4, a corresponding reworking of the reference element 120 (“matrix”) or of its reference surface 121 is carried out on the basis of the ascertained systematic errors. In doing so, aspects of the invention take advantage of the fact that—as schematically indicated in FIGS. 5A-5C—specific deviations among the respective surface shapes of the reference surface 521 of the reference element 520 and the test object surface 511 of the test object 510-in the sense of a “partial embodiment” of the test object 510 by the reference element 520 or the matrix—for the interferometric measurement of the test arrangement 100 are feasible. Unlike FIG. 4, the mirror specification shape according to FIG. 6, which is based on the interferometric testing of the respective mirror production, is adapted depending on this systematic error.

Although the invention has been described on the basis of specific embodiments, numerous variations and alternative embodiments, e.g. by combining and/or exchanging features of individual embodiments, can be discerned by a person skilled in the art. Accordingly, such variations and alternative embodiments are concomitantly encompassed by the present invention, and the scope of the invention is restricted only within the meaning of the appended patent claims and equivalents thereof.

1. A method for an interferometric determination of the surface shape of a test object, comprising:
in a test arrangement, superimposing a test wave, which is generated from electromagnetic radiation and has been reflected at the test object, with a reference wave, which is split off from the test wave in reflection, before being incident on the test object, at a reference surface of a reference element;
wherein the test object is configured for installation in an optical system in a specified installation position;
wherein a configuration of the reference surface is based on a measurement carried out in advance on the reference element in a measurement system in a specified installation position; and
determining the surface shape of the test object in the test arrangement, taking into account both the installation position of the test object in the optical system and the installation position of the reference element in the measurement system,
wherein either α₁<α<α₂ or α₁>α>α₂, with:
α₁=tilt angle of the test object in the test arrangement in the installation position in the optical system;
α₂=tilt angle of the reference element in the installation position in the measurement system; and
α=tilt angle of the test object in the test arrangement;
wherein the tilt angle is related in each case to the tilt of the test object or the reference element about an axis of rotation perpendicular to the plane of symmetry.

2. (canceled)

3. The method as claimed in cclaim 1, wherein the test object has a first stiffness (S₁) and the reference element has a second stiffness (S₂), wherein at least one of the following conditions is met:
$$for {S}_{1} < {S}_{2} : \vert α - {α}_{1} \vert < \vert α - {α}_{2} \vert ; \qquad a )$$
$$for {S}_{1} > {S}_{2} : \vert α - {α}_{1} \vert > \vert α - {α}_{2} \vert ; \qquad b )$$
$$for {S}_{1} = {S}_{2} : \vert α - {α}_{1} \vert = \vert α - {α}_{2} \vert = α / 2. \qquad c )$$

4. A method for an interferometric determination of the surface shape of a test object, comprising:
in a test arrangement, superimposing a test wave, which is generated from electromagnetic radiation and has been reflected at the test object, with a reference wave, which is split off from the test wave in reflection, before being incident on the test object, at a reference surface of a reference element;
wherein the test object is configured for installation in an optical system in a specified installation position;
wherein a configuration of the reference surface is based on a measurement carried out in advance on the reference element in a measurement system; and
determining the surface shape of the test object in the test arrangement, taking into account a systematic error contribution, which is ascertained on based on a plurality of system measurements, which are carried out in advance for a plurality of optical systems constructed with mutually different test objects.

5. The method as claimed in claim 4, wherein the systematic error contribution is taken into account by carrying out a reworking of the reference surface of the reference element, which depends on the systematic error contribution.

6. The method as claimed in claim 1, wherein the measurement system has a diffractive optical element which generates the test wave by diffraction of electromagnetic radiation.

7. The method as claimed in claim 6, wherein the diffractive optical element is a computer-generated hologram (CGH).

8. The method as claimed in claim 4, wherein the measurement system has a diffractive optical element which generates the test wave by diffraction of electromagnetic radiation.

9. The method as claimed in claim 8, wherein the diffractive optical element is a computer-generated hologram (CGH).

10. The method as claimed in claim 1, wherein the test object to be characterized with respect to the surface shape has an optical effective surface formed as a freeform surface without rotational symmetry.

11. The method as claimed in claim 4, wherein the test object to be characterized with respect to the surface shape has an optical effective surface formed as a freeform surface without rotational symmetry.

12. The method as claimed in claim 1, wherein the test object is a mirror or a lens element.

13. The method as claimed in claim 4, wherein the test object is a mirror or a lens element.

14. The method as claimed in claim 1, wherein the test object is configured for an operating wavelength of less than 30 nm.

15. The method as claimed in claim 14, wherein the test object is configured for an operating wavelength of less than 15 nm.

16. The method as claimed in claim 1, wherein the test object is a microlithographic optical element.

17. The method as claimed in claim 16, wherein the test object is an optical element of a microlithographic projection exposure apparatus.

18. The method as claimed in claim 4, wherein the test object is a microlithographic optical element.

19. The method as claimed in claim 18, wherein the test object is an optical element of a microlithographic projection exposure apparatus.
